(19) United States
(12) Patent Application Publication
(10) Pub. No.: US 2025/0372484 A1
(43) Pub. Date: Dec. 4, 2025

(54) SEMICONDUCTOR DEVICE

(71) Applicant: Rohm Co., Ltd., Kyoto (JP)

(72) Inventor: Kensei TAKAMOTO, Kyoto (JP)

(21) Appl. No.: 19/302,622

(22) Filed: Aug. 18, 2025

Related U.S. Application Data
(63) Continuation of application No. PCT/JP2024/004262, filed on Feb. 8, 2024.

(30) Foreign Application Priority Data
Feb. 24, 2023 (JP) 2023-027193

(51) Int. Cl. H01L 23/495; H01L 23/00; H01L 23/31

(52) U.S. Cl. CPC H01L 23/49537; H01L 23/3121; H01L 23/49513; H01L 23/49555; H01L 23/49565; H01L 24/32; H01L 2224/32245

(57) ABSTRACT

A semiconductor device includes a first conductive member having an island portion, a semiconductor element disposed on one side of a thickness direction of the island portion, and a sealing resin covering the semiconductor element and at least a part of the first conductive member. The island portion is located on one side of a first direction perpendicular to the thickness direction and includes a first edge portion extending in a second direction perpendicular to the thickness direction and the first direction. The first edge portion has a first step portion covered by the sealing resin and formed on one side of the second direction with respect to the semiconductor element in the second direction. The first step portion is recessed toward another side in the first direction, on the one side of the second direction rather than on another side of the second direction.

### TECHNICAL FIELD

The present disclosure relates to a semiconductor device.

### BACKGROUND ART

Semiconductor devices equipped with semiconductor elements have been proposed in various configurations. JP-A-2019-192751 discloses an example of a conventional semiconductor device. The semiconductor device disclosed in the same document includes leads, semiconductor elements, and sealing resin. The semiconductor elements are supported by the leads. The sealing resin covers a part of the leads and the semiconductor elements.

In the semiconductor device described in JP-A-2019-192751, the semiconductor device is bonded to the lead via a bonding material. In the above semiconductor device, each part expands and contracts due to heat generated by the semiconductor elements. The linear expansion coefficient of the sealing resin is larger than that of the semiconductor device and the lead. Due to this difference in linear expansion coefficients, relatively large stresses may act on the periphery and its vicinity of the semiconductor element due to the thermal contraction of the sealing resin. In such cases, defects such as bonding failure of the semiconductor element or cracking of the sealing resin may occur.

### BRIEF DESCRIPTION OF THE DRAWINGS

FIG. 1 is a perspective view of a semiconductor device according to a first embodiment of the present disclosure.

FIG. 2 is a partial perspective view of the semiconductor device according to the first embodiment of the present disclosure.

FIG. 3 is a plan view of the semiconductor device according to the first embodiment of the present disclosure.

FIG. 4 is a partial plan view of the semiconductor device according to the first embodiment of the present disclosure.

FIG. 5 is a bottom view of the semiconductor device according to the first embodiment of the present disclosure.

FIG. 6 is a partial bottom view of the semiconductor device according to the first embodiment of the present disclosure.

FIG. 7 is a side view of the semiconductor device according to the first embodiment of the present disclosure.

FIG. 8 is a cross-sectional view along line VIII-VIII in FIG. 4.

FIG. 9 is a cross-sectional view along line IX-IX in FIG. 4.

FIG. 10 is a cross-sectional view along line X-X in FIG. 4.

FIG. 11 is a cross-sectional view along line XI-XI in FIG. 4.

FIG. 12 is a partial enlarged view of FIG. 4.

FIG. 13 is a partial plan view of a semiconductor device according to a second embodiment of the present disclosure.

FIG. 14 is a partial bottom view of the semiconductor device according to the second embodiment of the present disclosure.

FIG. 15 is a cross-sectional view along line XV-XV in FIG. 13.

FIG. 16 is a partial plan view of a semiconductor device according to a third embodiment of the present disclosure.

FIG. 17 is a partial bottom view of the semiconductor device according to the third embodiment of the present disclosure.

FIG. 18 is a partial plan view of a semiconductor device according to a fourth embodiment of the present disclosure.

FIG. 19 is a partial bottom view of the semiconductor device according to the fourth embodiment of the present disclosure.

FIG. 20 is a partial plan view of a semiconductor device according to a fifth embodiment of the present disclosure.

FIG. 21 is a partial bottom view of the semiconductor device according to the fifth embodiment of the present disclosure.

### DETAILED DESCRIPTION OF EMBODIMENTS

The preferred embodiments of the present disclosure will now be described in detail with reference to the accompanying drawings.

The terms “first,” “second,” “third,” etc., used in the present disclosure are merely labels and do not necessarily indicate a specific order of the objects they refer to.

In this disclosure, unless otherwise specified, “object A is formed in object B” and “object A is formed on object B” include “object A is formed directly on object B” and “object A is formed on object B with another object interposed between object A and object B.” Similarly, unless otherwise specified, “object A is arranged in object B” and “object A is arranged on object B” include “object A is arranged directly on object B” and “object A is arranged on object B with another object interposed between object A and object B.” Similarly, unless otherwise specified, “object A is located on object B” includes “object A is in contact with object B and located on object B” and “object A is located on object B with another object interposed between object A and object B.” Furthermore, unless otherwise specified, “object A overlaps object B as viewed in a certain direction” includes “object A overlaps the whole of object B” and “object A overlaps a part of object B.” Furthermore, in this disclosure, “a surface A faces direction B (one side or the other side)” is not limited to cases where the angle between surface A and direction B is 90°, but also includes cases where surface A is tilted with respect to direction B.

### First Embodiment

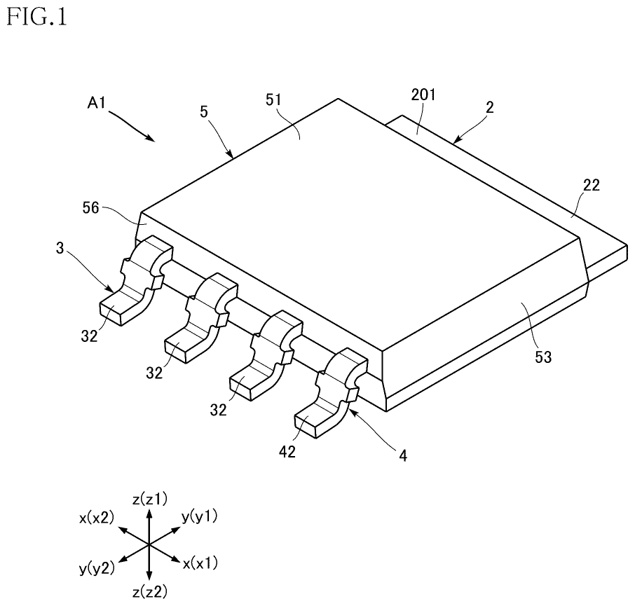

FIGS. 1 to 12 illustrate a semiconductor device according to a first embodiment of the present disclosure. In the present embodiment, the semiconductor device A1 includes a semiconductor element 1, a first conductive member 2, a second conductive member 3, a third conductive member 4, and a sealing resin 5. The application of the semiconductor device A1 is not limited, and it may be used in an electronic device having a power conversion circuit, such as a DC-DC converter.

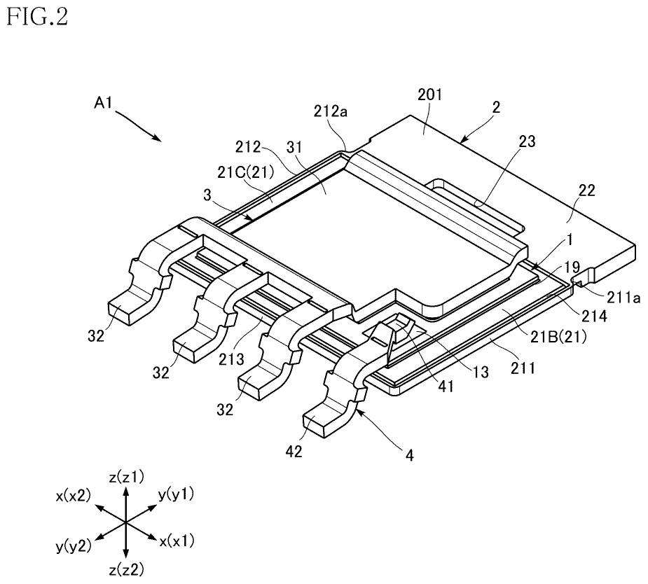

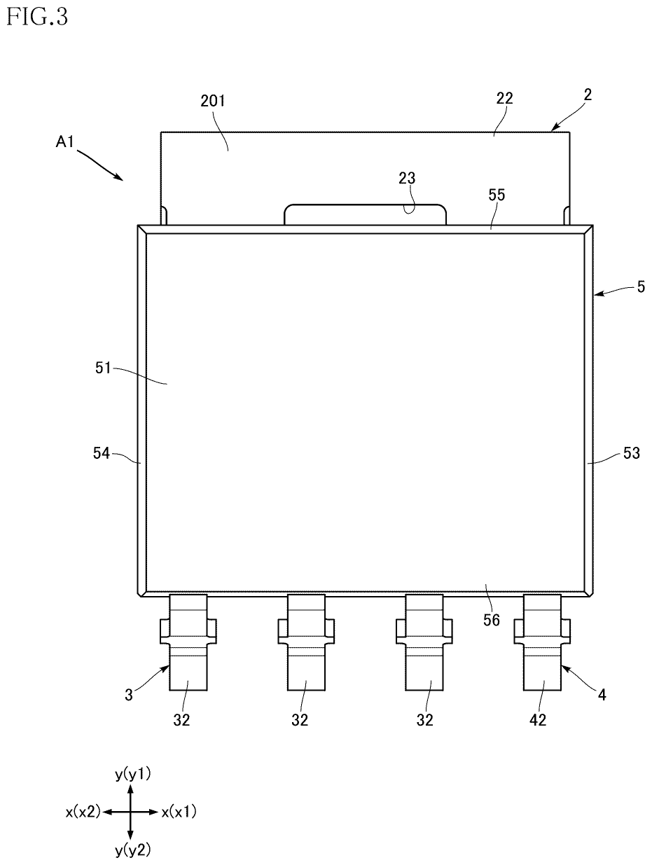

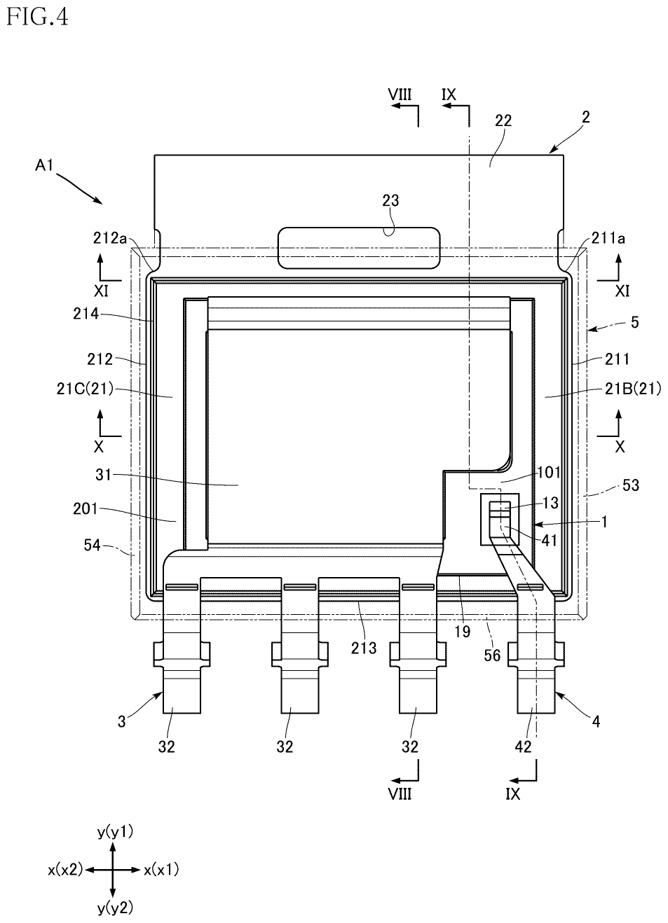

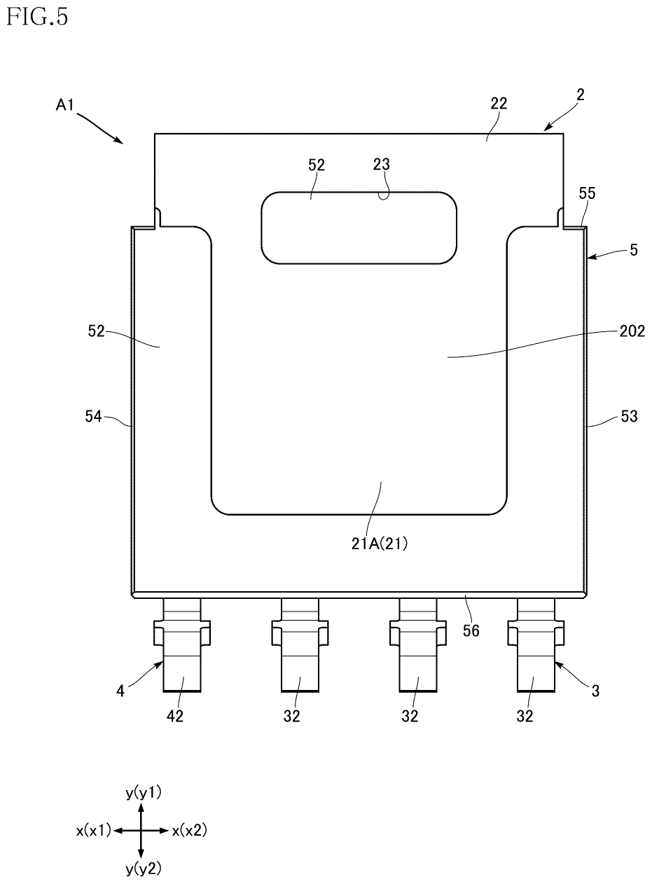

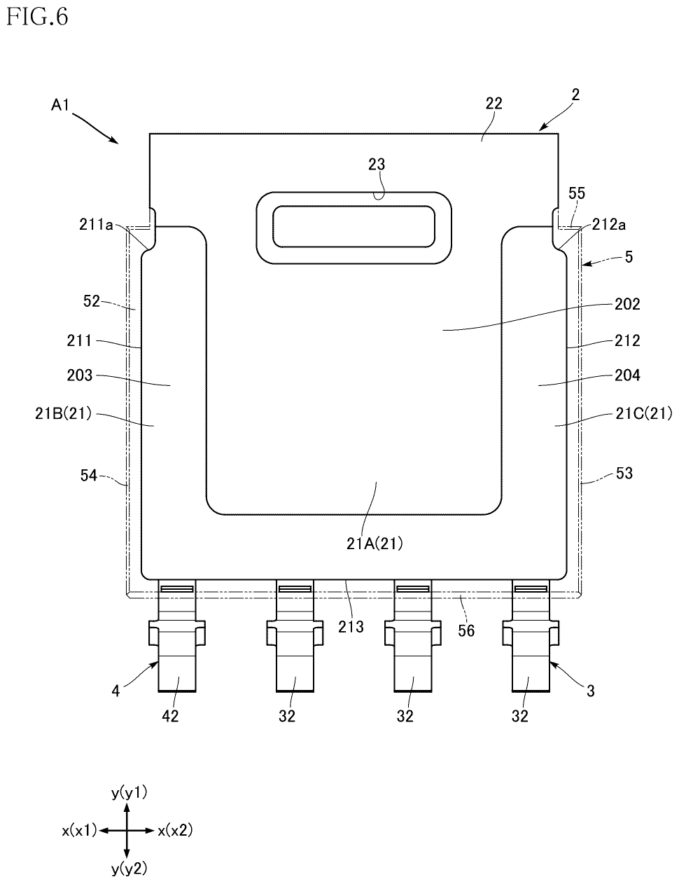

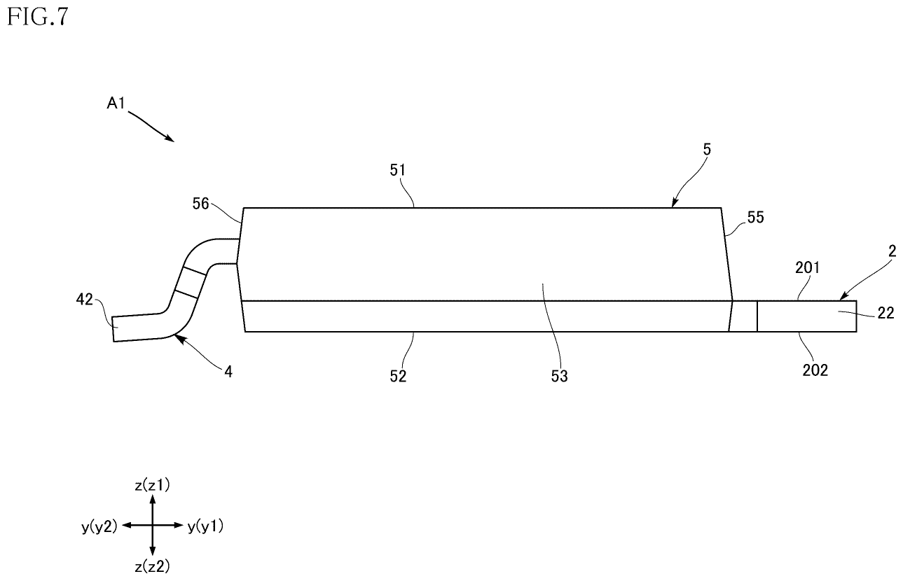

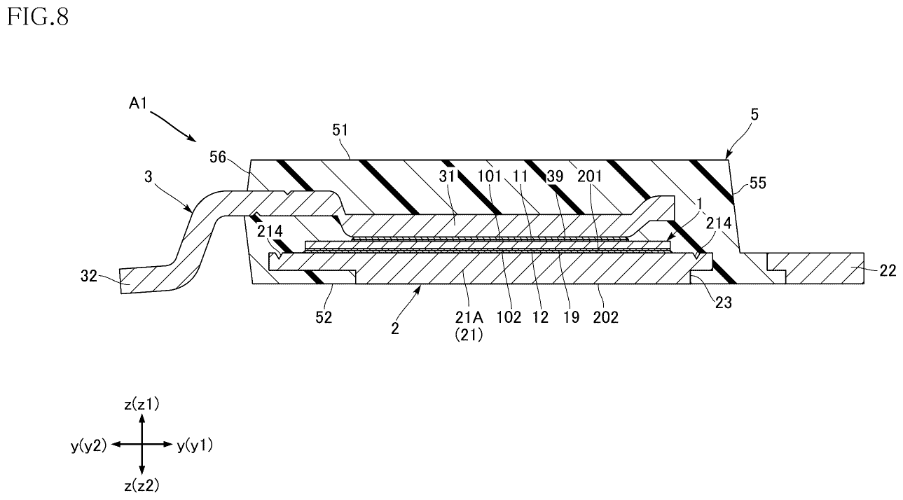

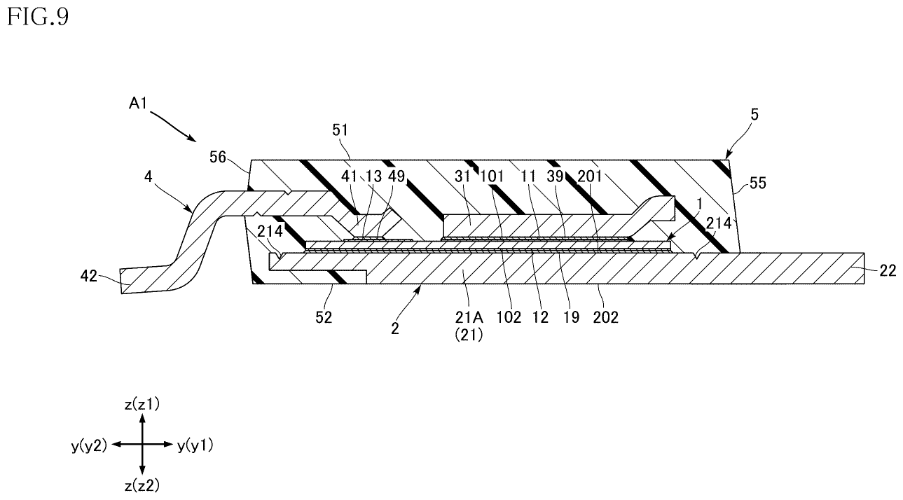

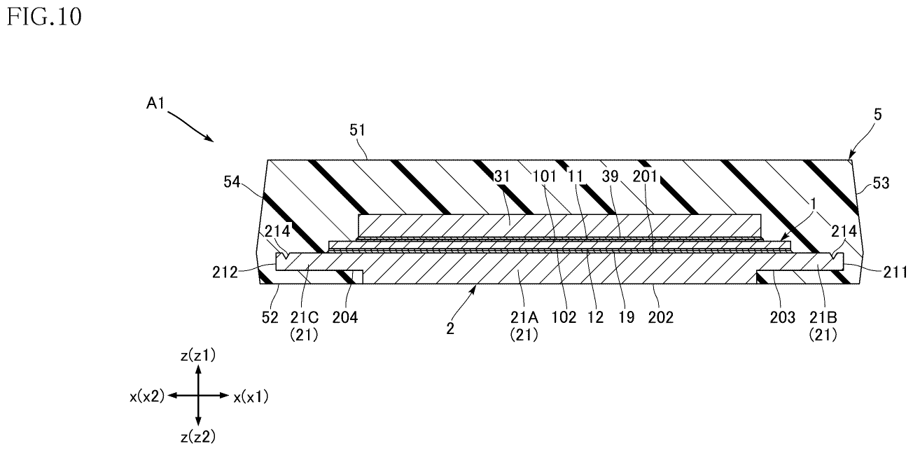

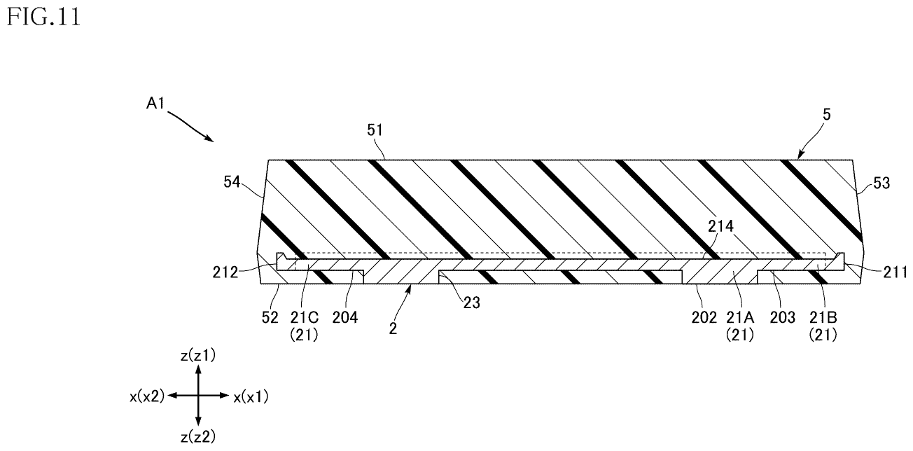

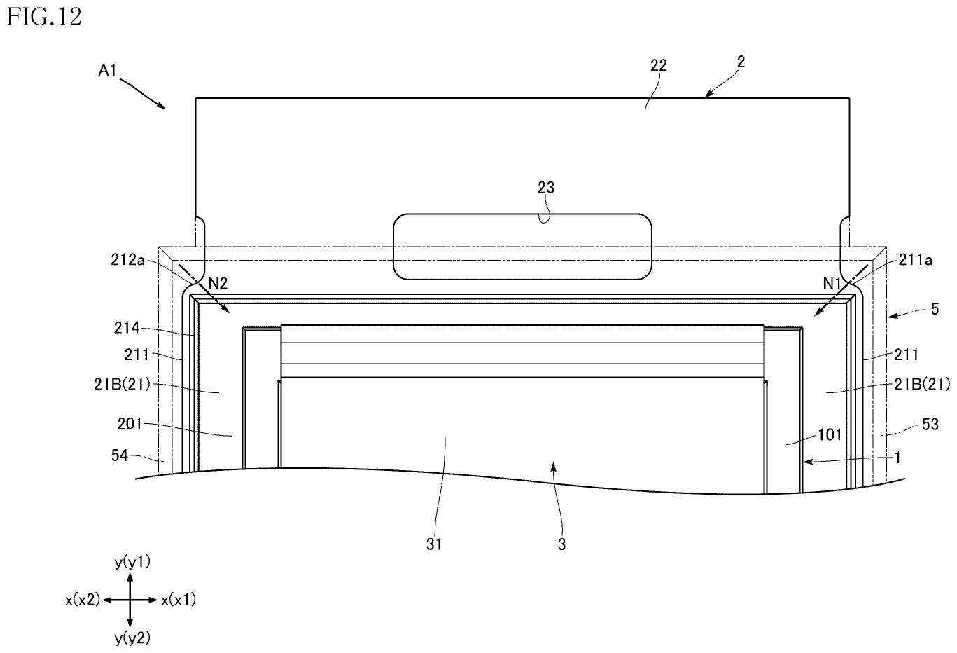

FIG. 1 is a perspective view of the semiconductor device A1. FIG. 2 is a partial perspective view of the semiconductor device A1, with the sealing resin 5 omitted. FIG. 3 is a plan view of the semiconductor device A1. FIG. 4 is a partial plan view of the semiconductor device A1, with the sealing resin 5 drawn as being transparent. FIG. 5 is a bottom view of the semiconductor device A1. FIG. 6 is a partial bottom view of the semiconductor device A1, with the scaling resin 5 drawn as being transparent. FIG. 7 is a side view of the semiconductor device A1. FIG. 8 is a cross-sectional view along the line VIII-VIII in FIG. 4. FIG. 9 is a cross-sectional view along line IX-IX in FIG. 4. FIG. 10 is a cross-sectional view along line X-X in FIG. 4. FIG. 11 is a cross-sectional view along line XI-XI in FIG. 4. FIG. 12 is a partial enlarged view of FIG. 4. Note that in FIGS. 4 and 6, the sealing resin 5 drawn as being transparent is indicated by imaginary lines (two-dot-dash lines).

In these figures, for example, an example of the thickness direction of the present disclosure is referred to as a “thickness direction z.” The direction orthogonal to the thickness direction z (the left-right direction in FIGS. 3 and 4) is an example of the first direction of the present disclosure and is referred to as a “first direction x.” The direction orthogonal to the thickness direction z and the first direction x (the up-down direction in FIGS. 3 and 4) is an example of the second direction of the present disclosure and is referred to as a “second direction y.” In FIGS. 3 and 4, the right side of the figures is an example of “one side of the first direction” of the present disclosure and is referred to as an “x1 side of the first direction x.” The left side of the figures is an example of the “another side of the first direction” of the present disclosure and is referred to as an “x2 side of the first direction x.” In FIGS. 3 and 4, the upper side of the figures is an example of “one side of the second direction” of the present disclosure and is referred to as a “y1 side of the second direction y.” The lower side of the figures is an example of the “another side of the second direction of the present disclosure and is referred to as a “y2 side of the second direction y.” Furthermore, in FIGS. 8 to 11, the upper side of the figures is an example of “one side of the thickness direction” of the present disclosure and is referred to as a “z1 side of the thickness direction z.” The lower side of the figures is an example of the “another side of the thickness direction” of the present disclosure and is referred to as a “z2 side of the thickness direction z.”

The semiconductor element 1 is an element that performs the electrical functions of the semiconductor device A1. In the present embodiment, the semiconductor element 1 is a three-terminal element having three electrodes, such as a MOSFET (Metal-Oxide-Semiconductor Field-Effect Transistor). Additionally, the semiconductor element 1 may be a switching element such as an IGBT (Insulated Gate Bipolar Transistor) or a diode. In the description of the semiconductor device A1, the semiconductor element 1 is an n-channel type and a vertical structure MOSFET. The semiconductor element 1 is rectangular as viewed in the thickness direction z.

The semiconductor element 1, as shown in FIGS. 2, 4, and 8 to 10, includes an element first surface 101, an element second surface 102, a first electrode 11, a second electrode 12, and a third electrode 13. The element first surface 101 and the element second surface 102 are separated in the thickness direction z and face opposite sides with each other. The element first surface 101 faces the z1 side in the thickness direction z. The element second surface 102 faces the z2 side in the thickness direction z.

The first electrode 11 is disposed on the element first surface 101. A current corresponding to the power converted by the semiconductor element 1 flows through the first electrode 11. That is, the first electrode 11 corresponds to the source electrode of the semiconductor element 1.

The second electrode 12 is disposed on the element second surface 102. A current corresponding to the power before conversion by the semiconductor element 1 flows through the second electrode 12. That is, the second electrode 12 corresponds to the drain electrode of the semiconductor element 1.

The third electrode 13 is disposed on the element first surface 101. A gate voltage for driving the semiconductor element 1 is applied to the third electrode 13. In other words, the third electrode 13 corresponds to the gate electrode of the semiconductor element 1. As viewed in the thickness direction z, the area of the third electrode 13 is smaller than the area of the first electrode 11.

The first conductive member 2 is disposed on the 22 side of the thickness direction z with respect to the semiconductor element 1. The first conductive member 2 includes a conductive material such as a metal, for example copper (Cu).

The first conductive member 2 has a first main surface 201 and a second main surface 202, as shown in FIGS. 1 to 10. The first main surface 201 is a surface facing the z1 side in the thickness direction z. The second main surface 202 is a surface facing the z2 side in the thickness direction z. The semiconductor element 1 is mounted on the first main surface 201. As shown in FIGS. 5 and 6, the second main surface 202 is exposed from the sealing resin 9.

The first conductive member 2, as shown in FIGS. 1 to 10, has an island portion 21, a first terminal portion 22, and a through hole 23.

The island portion 21 is a portion where the semiconductor element 1 is mounted in whole or in part. The island portion 21 has a part of the first main surface 201 and a part of the second main surface 202. The shape and size of the island portion 21 are not limited, and in the illustrated example, it is approximately rectangular as viewed in the thickness direction z.

The island portion 21 has a first edge portion 211, a second edge portion 212, a third edge portion 213, and a recessed groove 214, as shown in FIGS. 2, 4, 6, and 8 to 11. The first edge portion 211 is located on the x1 side of the first direction x and extends in the second direction y. The second edge portion 212 is located on the x2 side of the first direction x and extends in the second direction y. The third edge portion 213 is located on the y2 side of the second direction y and extends in the first direction x. The recessed groove 214 is recessed from the first main surface 201 in the thickness direction z toward the 22 side and has a cross-sectional shape resembling a V-shape. The recessed groove 214 surrounds the semiconductor element 1 as viewed in the thickness direction z. The first edge portion 211, the second edge portion 212, the third edge portion 213, and the recessed groove 214 are each covered by the sealing resin 5. Note that, unlike the illustrated example, the island portion 21 may have a configuration without the recessed groove 214.

The first edge portion 211 has a first step portion 211a, as shown in FIGS. 4 and 6. The first step portion 211a is formed on the y1 side of the second direction y with respect to the semiconductor element 1 in the second direction y. The first step portion 211a is shaped to be recessed toward the x2 side in the first direction x, on the y1 side of the second direction y rather than on the y2 side of the second direction y. In the present embodiment, the first step portion 211a is inclined with respect to the first direction x and the second direction y such that it is positioned toward the x2 side in the first direction x as it extends toward the y1 side in the second direction y.

The second edge portion 212 has a second step portion 212a. The second step portion 212a is formed on the y1 side of the second direction y with respect to the semiconductor element 1 in the second direction y. The second step portion 212a is shaped to be recessed toward the x1 side in the first direction x, on the y1 side of the second direction y rather than on the y2 side of the second direction y. In the present embodiment, the second step portion 212a is inclined with respect to the first direction x and the second direction y such that it is positioned toward the x1 side in the first direction x as it extends toward the y1 side in the second direction y.

In the present embodiment, the island portion 21 includes a main portion 21A, a first thin portion 21B, and a second thin portion 21C, as shown in FIGS. 4, 6, 10, and 11. The main portion 21A has a part of the first main surface 201 and a part of the second main surface 202.

The first thin portion 21B is a portion connected to the main portion 21A on the x1 side of the first direction x. The first thin portion 21B has a part of the first main surface 201 and the first intermediate surface 203. The first thin portion 21B does not include the second main surface 202. The first intermediate surface 203 faces the 22 side in the thickness direction z. The first intermediate surface 203 is located between the first main surface 201 and the second main surface 202 in the thickness direction z. As a result, the first thin portion 21B has a concave shape where the z2 side of the thickness direction z is recessed with respect to the main portion 21A. In the illustrated example, the first thin portion 21B includes all of the first edge portion 211. The first step portion 211a is formed in the first thin portion 21B.

The second thin portion 21C is a portion connected to the main portion 21A on the x2 side of the first direction x. The second thin portion 21C has a part of the first main surface 201 and the second intermediate surface 204. The second thin portion 21C does not include the second main surface 202. The second intermediate surface 204 faces the 22 side in the thickness direction z. The second intermediate surface 204 is located between the first main surface 201 and the second main surface 202 in the thickness direction z. As a result, the second thin portion 21C has a shape where the z2 side of the thickness direction z is recessed with respect to the main portion 21A. In the illustrated example, the second thin portion 21C includes all of the second edge portion 212. The second step portion 212a is formed in the first thin portion 21B.

As shown in FIGS. 4, 10 and so forth, the semiconductor element 1 overlaps the main portion 21A and the first thin portion 21B as viewed in the thickness direction z. Additionally, the semiconductor element 1 overlaps the main portion 21A and the second thin portion 21C as viewed in the thickness direction z.

As shown in FIGS. 8 to 10, the semiconductor element 1 is bonded to the first main surface 201 of the island portion 21 via a conductive bonding material 19. The element second surface 102 of the semiconductor element 1 is opposed to the first main surface 201. The second electrode 12 on the element second surface 102 and the first main surface 201 are conductively bonded via the conductive bonding material 19. The specific configuration of the conductive bonding material 19 is not particularly limited and may, for example, be solder (a metal containing tin and silver). Additionally, the conductive bonding material 19 may be formed using a metal paste containing a metal such as silver (Ag). Furthermore, in the region of the first main surface 201 of the island portion 21 where the semiconductor element 1 is bonded, a plating layer composed of silver (Ag), for example, may be formed.

The first terminal portion 22 is the portion connected to the island portion 21 on the y1 side of the second direction y. The first terminal portion 22 has a part of the first main surface 201 and a part of the second main surface 202. The first terminal portion 22 may be used as a terminal when mounting the semiconductor device A1.

The through hole 23 penetrates the first conductive member 2 in the thickness direction z. In the present embodiment, the through hole 23 is filled with a part of the sealing resin 5. Furthermore, the size of the cross-section perpendicular to the thickness direction z of the through hole 23 is larger on the z1 side of the thickness direction z than on the 22 side of the thickness direction z. This has the effect of, for example, suppressing the first conductive member 2 from detaching from the sealing resin 5.

The part of the first conductive member 2 exposed from the sealing resin 5 may be formed with a plating layer composed of an alloy containing tin (Sn) as the main component, for example.

The second conductive member 3 has a portion disposed on the z1 side of the thickness direction z with respect to the semiconductor element 1. The second conductive member 3 includes conductive materials such as metals, and for example, it includes Cu (copper). The second conductive member 3 has a pad portion 31 and a plurality second terminal portions 32, as shown in FIGS. 1 to 6 and FIGS. 8 to 10.

The pad portion 31 is a portion that is conductively bonded to the first electrode 11 of the semiconductor element 1. The shape and size of the pad portion 31 are not limited, and in the illustrated example, it has a shape that overlaps most of the first electrode 11 as viewed in the thickness direction z and exposes the third electrode 13.

As shown in FIGS. 8 to 10, the pad portion 31 is bonded to the first electrode 11 of the semiconductor element 1 via a conductive bonding material 39. The pad portion 31 and the first electrode 11 are conductively bonded to each other via the conductive bonding material 39. The specific configuration of the conductive bonding material 39 is not particularly limited and may, for example, be solder (a metal containing tin and silver). Additionally, the conductive bonding material 39 may be formed using a metal paste containing a metal such as silver (Ag). Furthermore, in the region of the pad portion 31 that is bonded to the semiconductor element 1 (first electrode 11), a plating layer composed of silver (Ag), for example, may be formed.

The plurality of second terminal portions 32 are connected to the pad portion 31 on the y2 side of the second direction y. The second terminal portions 32 each extend in the second direction y as viewed in the thickness direction z and are arranged at intervals in the first direction x. The number of the plurality of second terminal portions 32 is not limited, and may be three as shown in the example, two, four or more. Further, the configuration of having only one second terminal portion 32 is also possible. As shown in FIGS. 1, 2, and 8, the second terminal portion 32 has a portion connected to the pad portion 31 and covered by the scaling resin 5, a portion protruding from the sealing resin 5 toward the y2 side in the second direction y, a portion folded back toward the 22 side in the thickness direction z, and a portion located on the z2 side of the thickness direction z. The plurality of second terminal portions 32 are used as terminals when mounting the semiconductor device A1.

The portions of the second conductive member 3 (the plurality of second terminal portions 32) exposed from the sealing resin 5 may be formed with a plating layer composed of an alloy containing tin (Sn) as the main component.

The third conductive member 4 has a portion disposed on the z1 side of the thickness direction z with respect to the semiconductor element 1. The third conductive member 4 includes conductive materials such as metal and may include, for example, Cu (copper). The third conductive member 4 has pad portion 41 and a third terminal portion 42, as shown in FIGS. 1 to 7, 9, and 10.

The pad portion 41 is a portion conductively bonded to the third electrode 13 of the semiconductor element 1. The shape and size of the pad portion 41 are not limited, and in the illustrated example, it has a shape that overlaps a part of the third electrode 13 as viewed in the thickness direction z and exposes the third electrode 13.

As shown in FIG. 9, the pad portion 41 is bonded to the third electrode 13 of the semiconductor element 1 via a conductive bonding material 49. The pad portion 41 and the third electrode 13 are conductively bonded to each other via the conductive bonding material 49. The specific configuration of the conductive bonding material 49 is not particularly limited and may, for example, be solder (a metal containing tin and silver). Additionally, the conductive bonding material 49 may be formed using a metal paste containing a metal such as silver (Ag). Furthermore, a plating layer composed of silver (Ag), for example, may be formed in the region of the pad portion 41 that is bonded to the semiconductor element 1 (third electrode 13).

The third terminal portion 42 is connected to the pad portion 41 on the y2 side of the second direction y. The third terminal portion 42 extends in the second direction y as viewed in the thickness direction z. As shown in FIGS. 1, 2, 7, and 9, the third terminal portion 42 has a portion connected to the pad portion 41 and covered by the sealing resin 5, a portion protruding from the sealing resin 5 toward the y2 side in the second direction y, a portion folded back toward the 22 side in the thickness direction z, and a portion located on the 22 side of the thickness direction z. As viewed in the first direction x, the third terminal portion 42 has a shape and size that substantially overlaps the second terminal portion 32. The third terminal portion 42 is used as a terminal when mounting the semiconductor device A1.

The part of the third conductive member 4 (third terminal portion 42) exposed from the sealing resin 5 may be formed with a plating layer composed of an alloy containing tin (Sn), for example, as the main component.

The sealing resin 5 covers portions of the semiconductor element 1, and each of the first conductive member 2, the second conductive member 3, and the third conductive member 4. The sealing resin 5 has electrical insulating properties. The sealing resin 5 includes, for example, a black epoxy resin containing a filler. The shape of the sealing resin 5 is not limited. As shown in FIGS. 1 and 3 to 11, the sealing resin 5 of the present embodiment has a first resin surface 51, a second resin surface 52, a third resin surface 53, a fourth resin surface 54, a fifth resin surface 55, and a sixth resin surface 56.

The first resin surface 51 is a surface facing the z1 side in the thickness direction z. The second resin surface 52 is a surface facing the z2 side in the thickness direction z. From the second resin surface 52, the second main surface 202 of the first conductive member 2 is exposed. In the illustrated example, the first resin surface 51 and the second resin surface 52 are flat surfaces, but they are not limited thereto and may, for example, be curved surfaces or bent surfaces. In the illustrated example, the second resin surface 52 and the second main surface 202 are coplanar.

The third resin surface 53 is a surface facing the x1 side in the first direction x. The fourth resin surface 54 is a surface facing the x2 side in the first direction x. In the illustrated example, the third resin surface 53 and the fourth resin surface 54 are slightly curved surfaces, but they are not limited to thereto, and may be, for example, curved surfaces or flat surfaces.

The fifth resin surface 55 is a surface facing the y1 side in the second direction y. The sixth resin surface 56 is a surface facing the y2 side in the second direction y. In the illustrated example, the fifth resin surface 55 and the sixth resin surface 56 are slightly curved surfaces, but they are not limited thereto, and may be, for example, curved surfaces or flat surfaces. In the present embodiment, the first terminal portion 22 protrudes from the fifth resin surface 55, and the plurality of second terminal portions 32 and third terminal portion 42 protrude from the sixth resin surface 56.

Next, the operation of the semiconductor device A1 will be described.

In the semiconductor device A1, the first edge portion 211 of the island portion 21 has the first step portion 211a. The first edge portion 211 is located on the x1 side of the first direction x of the island portion 21 and extends in the second direction y. The first step portion 211a is formed on the y1 side of the second direction y with respect to the semiconductor element 1 and is covered by the sealing resin 5. The first step portion 211a is recessed toward the x2 side in the first direction x, on the y1 side of the second direction y rather than on the y2 side of the second direction y. With this configuration, when thermal expansion and contraction occur in each part due to heat generated by the semiconductor element 1, the thermal contraction of the sealing resin 5 (indicated by arrow N1 in FIG. 12) can be accommodated by the first step portion 211a. As a result, the stress acting on and near the periphery of the semiconductor element 1 (near the corner of the semiconductor element 1 on the x1 side of the first direction x and on the y1 side of the second direction y) can be reduced.

The second edge portion 212 of the island portion 21 has the second step portion 212a. The second step portion 212a is located on the x2 side of the first direction x of the island portion 21 and extends in the second direction y. The second step portion 212a is formed on the y1 side of the second direction y with respect to the semiconductor element 1 and is covered by the sealing resin 5. The second step portion 212a is recessed toward the x1 side in the first direction x, on the y1 side of the second direction y rather than on the y2 side of the second direction y. With this configuration, the thermal contraction of the sealing resin 5 (indicated by arrow N2 in FIG. 12) can be accommodated by the second step portion 212a. As a result, the stress acting on and near the periphery of the semiconductor element 1 (near the corner of the semiconductor element 1 on the x2 side of the first direction x and the y1 side of the second direction y) can be reduced.

The island portion 21 has the main portion 21A, the first thin portion 21B, and the second thin portion 21C. The main portion 21A has a part of the first main surface 201 and a part of the second main surface 202. The first thin portion 21B is connected to the main portion 21A on the x1 side of the first direction x, and has a part of the first main surface 201 and the first intermediate surface 203. The first intermediate surface 203 faces the 22 side in the thickness direction z and is located between the first main surface 201 and the second main surface 202 in the thickness direction z. The second thin portion 21C is connected to the main portion 21A on the x2 side of the first direction x, and has a part of the first main surface 201 and the second intermediate surface 204. The second intermediate surface 204 faces the 22 side in the thickness direction z and is located between the first main surface 201 and the second main surface 202 in the thickness direction z. The semiconductor element 1 overlaps the main portion 21A, the first thin portion 21B, and the second thin portion 21C as viewed in the thickness direction z. With this configuration, as above, it is possible to reduce the stress acting on and near the periphery of the semiconductor element 1 while enlarging the size of the semiconductor element 1 mounted on the island portion 21.

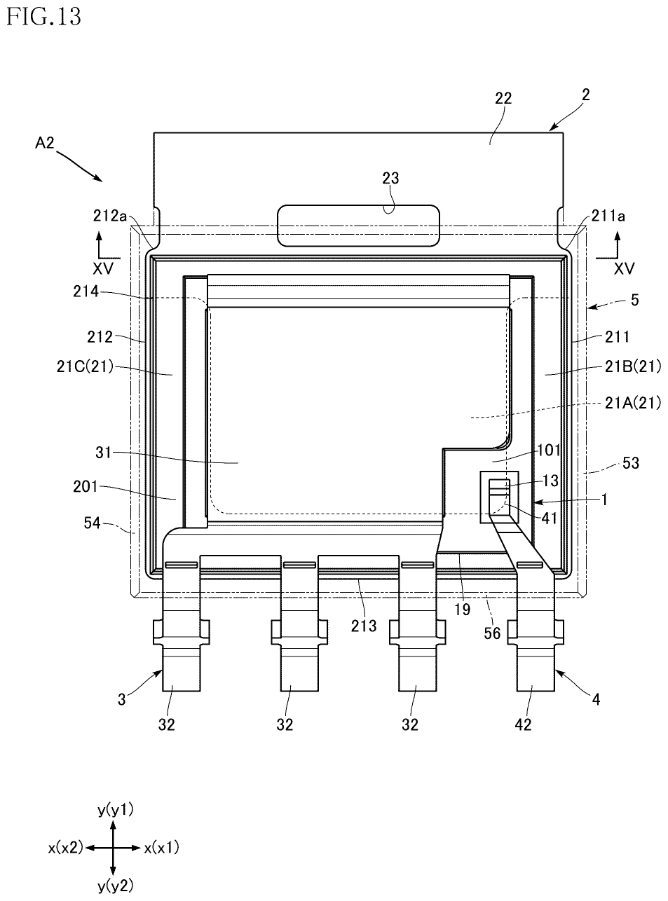

FIGS. 13 to 21 illustrate other embodiments of the present disclosure. In these figures, elements identical or similar to those in the above embodiment are denoted by the same reference numerals used in the above embodiment, and redundant descriptions are omitted. Furthermore, the configurations of each part in each embodiment may be appropriately combined with each other within the scope of not causing technical contradictions.

### Second Embodiment

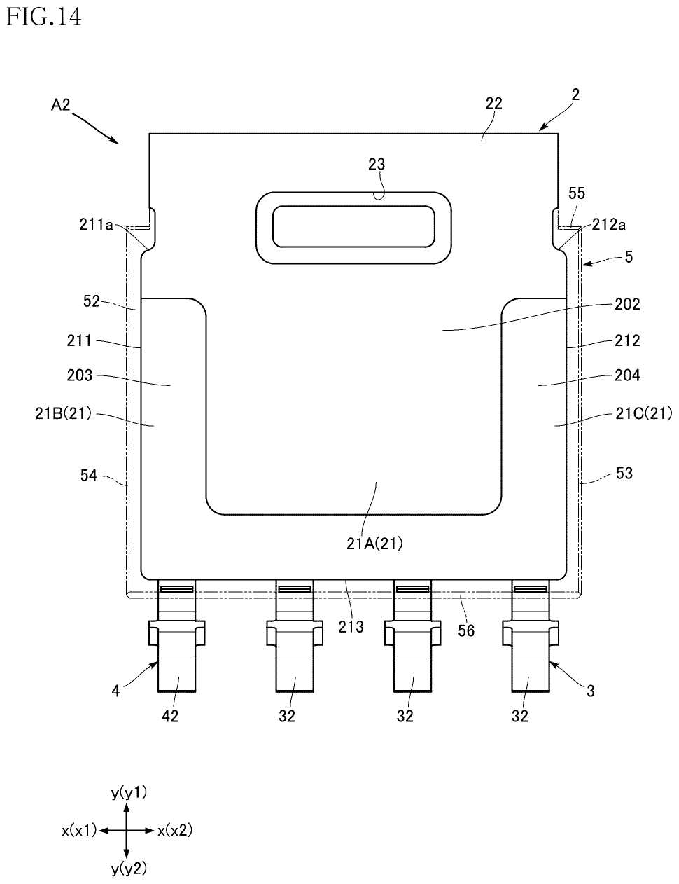

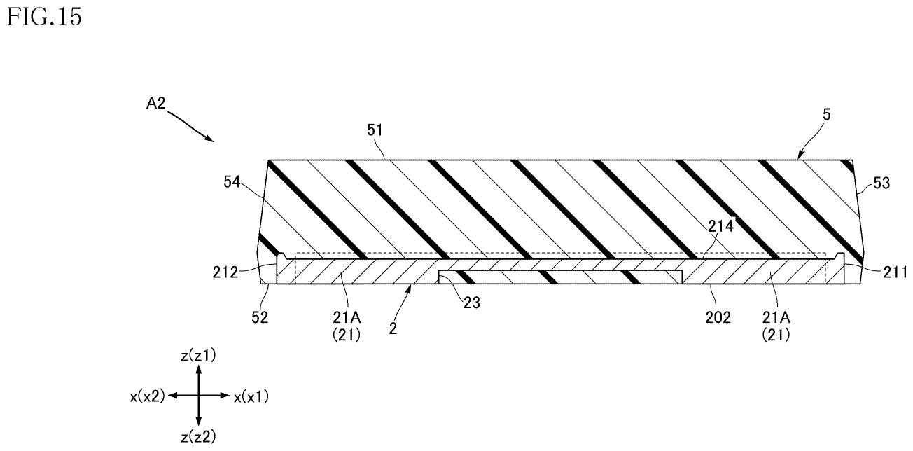

FIGS. 13 to 15 illustrate a semiconductor device according to a second embodiment of the present disclosure. FIG. 13 is a partial plan view of the semiconductor device A2 of the present embodiment, showing the sealing resin 5 as being transparent. FIG. 14 is a partial bottom view of the semiconductor device A2, showing the sealing resin 5 as being transparent. FIG. 15 is a cross-sectional view along line XV-XV in FIG. 13. Note that in FIGS. 13 and 14, the sealing resin 5 as being transparent is indicated by imaginary lines (two-dot-dash lines).

The semiconductor device A2 differs from the above embodiment in the formation regions of the main portion 21A, the first thin portion 21B, and the second thin portion 21C in the island portion 21. As shown in FIG. 14, in the semiconductor device A2, the formation region of the main portion 21A is larger than that of the semiconductor device A1 in the above embodiment.

As shown in FIG. 14, in the semiconductor device A2, the first step portion 211a and the second step portion 212a are formed in the main portion 21A.

In the semiconductor device A2, the first step portion 211a of the island portion 21 is formed on the y1 side of the second direction y with respect to the semiconductor element 1 in the second direction y and is covered by the sealing resin 5. The first step portion 211a is recessed toward the x2 side in the first direction x, on the y1 side of the second direction y rather than on the y2 side of the second direction y. With this configuration, the thermal contraction of the sealing resin 5 can be accommodated by the first step portion 211a. As a result, stress acting on and near the periphery of the semiconductor element 1 (near the corner of the semiconductor element 1 on the x1 side of the first direction x and on the y1 side of the second direction y) can be reduced.

The second step portion 212a of the island portion 21 is formed on the y1 side of the second direction y with respect to the semiconductor element 1 in the second direction y and is covered by the sealing resin 5. The second step portion 212a is recessed toward the x1 side in the first direction x, on the y1 side of the second direction y rather than on the y2 side of the second direction y. With this configuration, the thermal contraction of the sealing resin 5 can be accommodated by the second step portion 212a. As a result, the stress acting on and near the periphery of the semiconductor element 1 (near the corner of the semiconductor element 1 on the x2 side of the first direction x and on the y1 side of the second direction y) can be reduced.

In the semiconductor device A2, the first step portion 211a and the second step portion 212a are formed in the main portion 21A. With this configuration, it is possible to accommodate the thermal contraction of the sealing resin 5 with an area larger than that. This is more favorable in reducing the stress acting on and near the periphery of the semiconductor element 1.

The semiconductor element 1 overlaps the main portion 21A, the first thin portion 21B, and the second thin portion 21C as viewed in the thickness direction z. This configuration allows the size of the semiconductor element 1 mounted on the island portion 21 to be enlarged while reducing the stress acting on and near the periphery of the semiconductor element 1.

### Third Embodiment

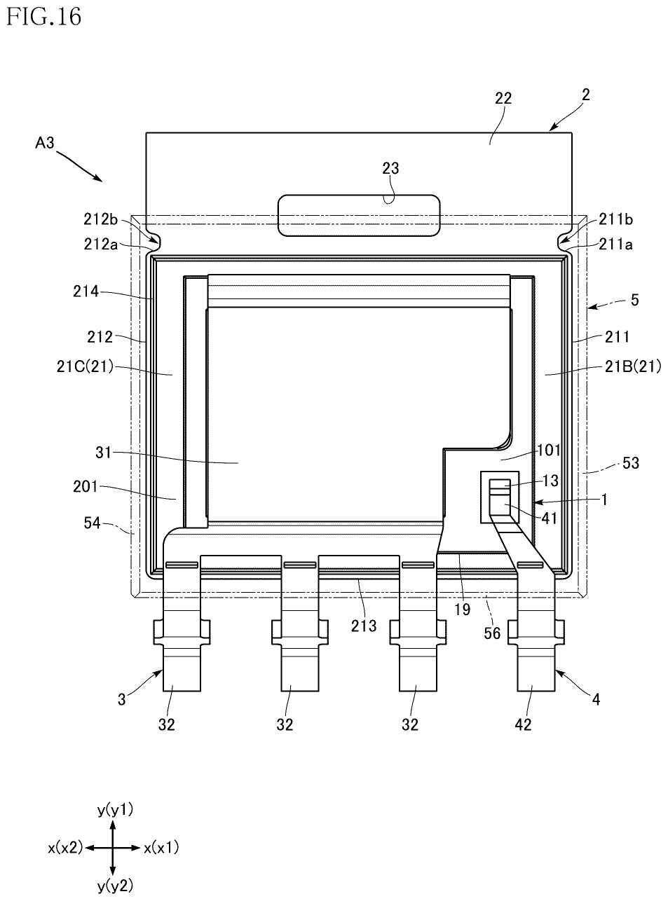

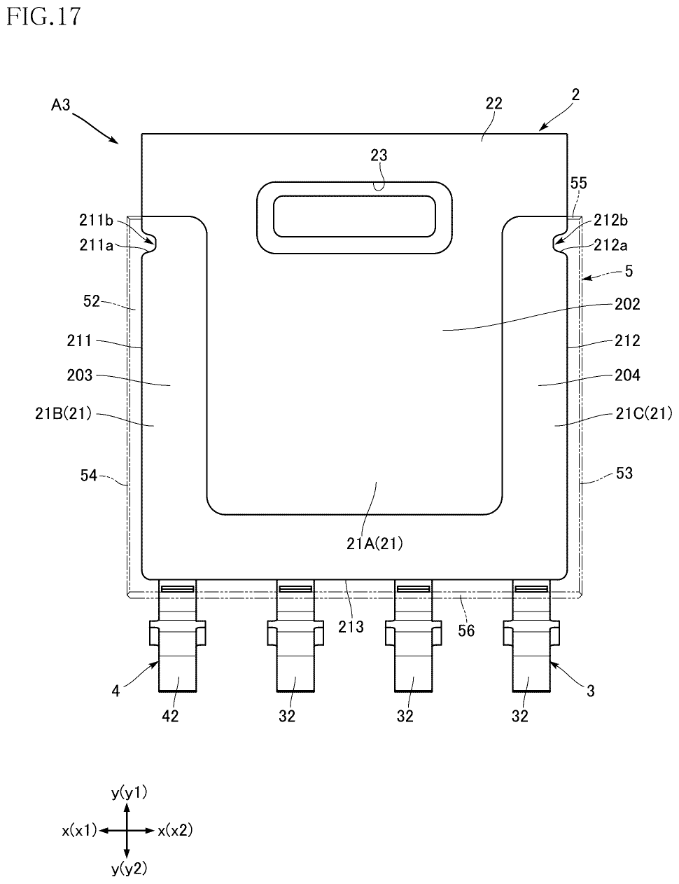

FIGS. 16 and 17 illustrate a semiconductor device according to a third embodiment of the present disclosure. FIG. 16 is a partial plan view of the semiconductor device A3 of present embodiment, showing the sealing resin 5 as being transparent. FIG. 17 is a partial bottom view of the semiconductor device A3, showing the sealing resin 5 as being transparent. Note that in FIGS. 16 and 17, the sealing resin 5 as being transparent is indicated by imaginary lines (two-dot-dash lines).

The semiconductor device A3 differs from the above embodiments regarding the configuration of the first edge portion 211 and the second edge portion 212.

As shown in FIGS. 16 and 17, the first edge portion 211 has a first recess 211b. The first recess 211b is formed on the y1 side of the second direction y of the semiconductor element 1 in the second direction y. The first recess 211b is recessed on the x2 side of the first direction x and includes the first step portion 211a.

The second edge portion 212 has a second recess 212b. The second recess 212b is formed on the y1 side of the second direction y of the semiconductor element 1 in the second direction y. The second recess 212b is recessed toward the x1 side in the first direction x and includes the second step portion 212a.

In the semiconductor device A3, the first step portion 211a of the island portion 21 is formed on the y1 side of the second direction y with respect to the semiconductor element 1 in the second direction y and is covered by the sealing resin 5. The first step portion 211a is recessed toward the x2 side in the first direction x, on the y1 side of the second direction y rather than on the y2 side of the second direction y. With this configuration, the thermal contraction of the sealing resin 5 can be accommodated by the first step portion 211a. As a result, stress acting on and near the periphery of the semiconductor element 1 (near the corner of the semiconductor element 1 on the x1 side of the first direction x and on the y1 side of the second direction y) can be reduced.

The second step portion 212a of the island portion 21 is formed on the y1 side of the second direction y with respect to the semiconductor element 1 in the second direction y and is covered by the sealing resin 5. The second step portion 212a is recessed toward the x1 side in the first direction x, on the y1 side of the second direction y rather than on the y2 side of the second direction y. With this configuration, the thermal contraction of the sealing resin 5 can be accommodated by the second step portion 212a. As a result, the stress acting on and near the periphery of the semiconductor element 1 (near the corner of the semiconductor element 1 on the x2 side of the first direction x and on the y1 side of the second direction y) can be reduced.

The semiconductor element 1 overlaps the main portion 21A, the first thin portion 21B, and the second thin portion 21C as viewed in the thickness direction z. With this configuration, it is possible to reduce the stress acting on and near the periphery of the semiconductor element 1 while expanding the size of the semiconductor element 1 mounted on the island portion 21.

### Fourth Embodiment

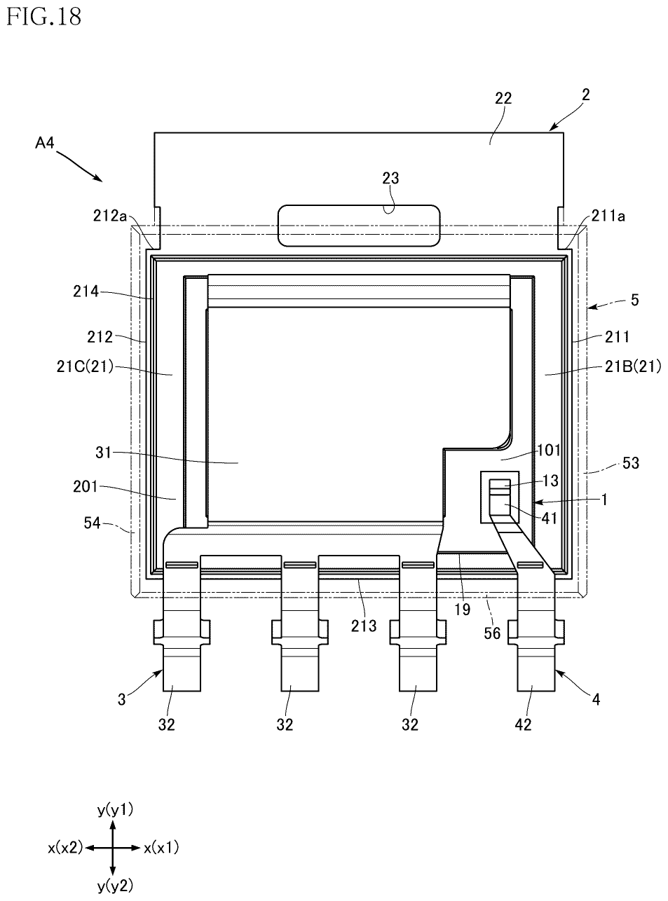

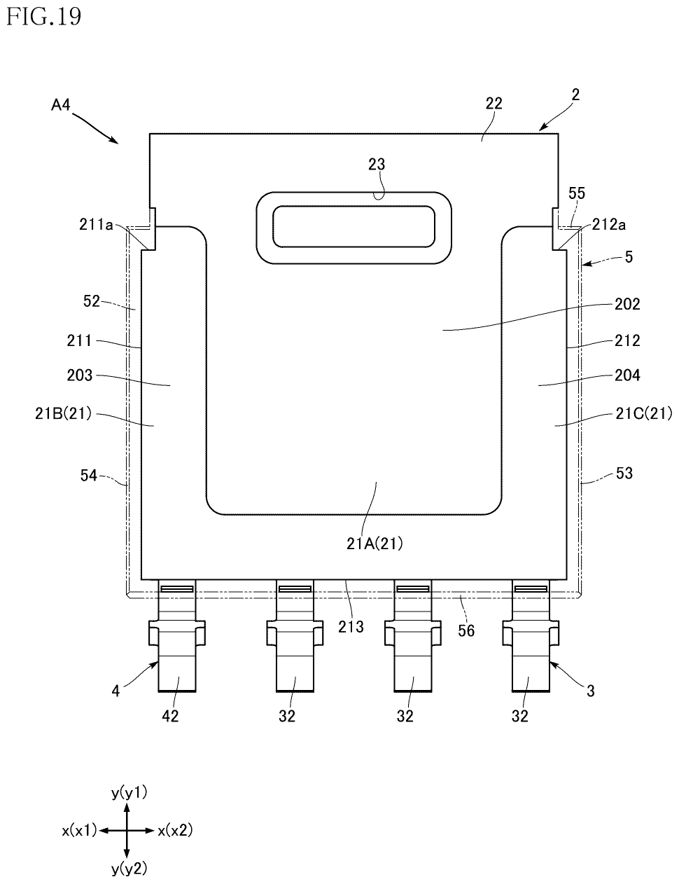

FIGS. 18 and 19 illustrate a semiconductor device according to a fourth embodiment of the present disclosure. FIG. 18 is a partial plan view of the semiconductor device A4 of present embodiment, showing the scaling resin 5 as being transparent. FIG. 19 is a partial bottom view of the semiconductor device A4, showing the sealing resin 5 as being transparent. Note that in FIGS. 18 and 19, the sealing resin 5 as being transparent is indicated by imaginary lines (two-dot-dash lines).

The semiconductor device A4 differs from that of the above embodiments in the configuration of the first step portion 211a and the second step portion 212a.

As shown in FIGS. 18 and 19, in the semiconductor device A4, the first step portion 211a is perpendicular or substantially perpendicular to the second direction y as viewed in the thickness direction z. The first recess 211b is perpendicular or substantially perpendicular to the second direction y as viewed in the thickness direction z.

In the semiconductor device A4, the first step portion 211a of the island portion 21 is formed on the y1 side of the second direction y with respect to the semiconductor element 1 in the second direction y and is covered by the sealing resin 5. The first step portion 211a is recessed toward the x2 side in the first direction x, on the y1 side of the second direction y rather than on the y2 side of the second direction y. With this configuration, the thermal contraction of the scaling resin 5 can be accommodated by the first step portion 211a. As a result, stress acting on and near the periphery of the semiconductor element 1 (near the corner of the semiconductor element 1 on the x1 side of the first direction x and on the y1 side of the second direction y) can be reduced.

The second step portion 212a of the island portion 21 is formed on the y1 side of the second direction y with respect to the semiconductor element 1 in the second direction y and is covered by the sealing resin 5. The second step portion 212a is recessed toward the x1 side in the first direction x, on the y1 side of the second direction y rather than on the y2 side of the second direction y. With this configuration, the thermal contraction of the sealing resin 5 can be accommodated by the second step portion 212a. As a result, the stress acting on and near the periphery of the semiconductor element 1 (near the corner of the semiconductor element 1 on the x2 side of the first direction x and on the y1 side of the second direction y) can be reduced.

The semiconductor element 1 overlaps the main portion 21A, the first thin portion 21B, and the second thin portion 21C as viewed in the thickness direction z. With this configuration, it is possible to reduce the stress acting on and near the periphery of the semiconductor element 1 while expanding the size of the semiconductor element 1 mounted on the island portion 21.

### Fifth Embodiment

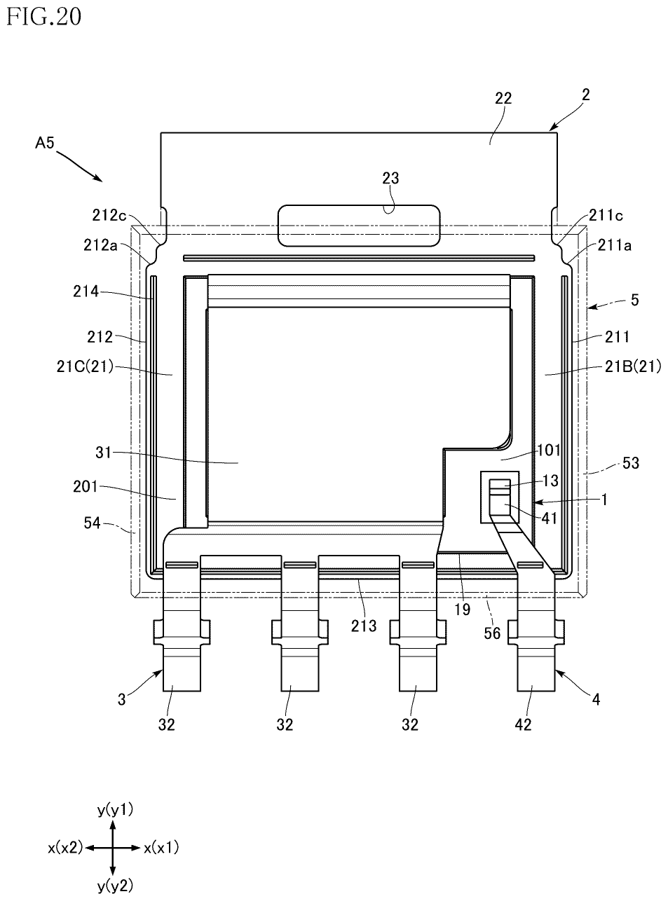

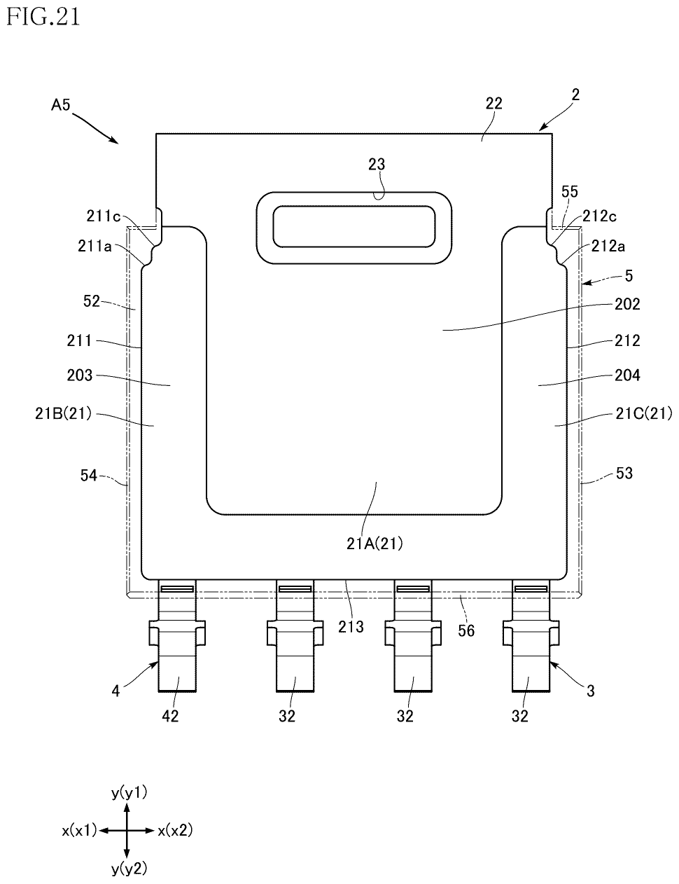

FIGS. 20 and 21 illustrate a semiconductor device according to a fifth embodiment of the present disclosure. FIG. 20 is a partial plan view of the semiconductor device A5 of present embodiment, showing the sealing resin 5 as being transparent. FIG. 21 is a partial bottom view of the semiconductor device A5, showing the scaling resin 5 as being transparent. Note that in FIGS. 20 and 21, the sealing resin 5 as being transparent is indicated by imaginary lines (two-dot-dash lines).

The semiconductor device A5 differs from the above embodiments in the configuration of the first edge portion 211 and the second edge portion 212. In the semiconductor device A5, the first edge portion 211 further has a first step portion 211c, and the second edge portion 212 further includes a second step portion 212c.

In the semiconductor device A5, the first edge portion 211 has two first step portions 211a and 211c. The first step portion 211c is adjacent in the second direction y to the first step portion 211a on the y1 side of the second direction y. The first step portion 211c is shaped to be recessed toward the x2 side in the first direction x, on the side of the second direction y rather than on the y2 side of the second direction y. Thus, in the semiconductor device A5, the first edge portion 211 has first step portions 211a and 211c that are recessed in two steps.

The second edge portion 212 has the two second step portions 212a and 212c. The second step portion 212c is adjacent in the second direction y to the second step portion 212a and is on the y1 side of the second direction y therefrom. The second step portion 212c is shaped to be recessed toward the x1 side in the first direction x, on the y1 side of the second direction y rather than on the y2 side of the second direction y. Thus, the second edge portion 212 has the second step portions 212a and 212c that are recessed in two steps.

In the semiconductor device A5, the recessed groove 214 is not formed near the first step portions 211a and 211c or near the second step portions 212a and 212c.

In the semiconductor device A5, the first step portions 211a and 211c of the island portion 21 are formed on the y1 side of the second direction y with respect to the semiconductor element 1 and are covered by the sealing resin 5. Each of the first step portions 211a and 211c is recessed toward the x2 side in the first direction x, on the y1 side of the second direction y rather than on the y2 side of the second direction y. With this configuration, the thermal contraction of the sealing resin 5 can be accommodated by the two first step portions 211a and 211c. As a result, the stress acting on and near the periphery of the semiconductor element 1 (near the corner of the semiconductor element 1 on the x1 side of the first direction x and on the y1 side of the second direction y) can be reduced.

The second step portions 212a and 212c of the island portion 21 are formed on the y1 side of the second direction y with respect to the semiconductor element 1 and are covered by the sealing resin 5. Each of the second step portions 212a and 212c is recessed toward the x1 side in the first direction x, on the y1 side of the second direction y rather than on the y2 side of the second direction y. With this configuration, the thermal contraction of the sealing resin 5 can be accommodated by the two second step portions 212a and 212c. As a result, the stress acting on and near the periphery of the semiconductor element 1 (near the corner of the semiconductor element 1 on the x2 side of the first direction x and on the y1 side of the second direction y) can be reduced.

The semiconductor element 1 overlaps the main portion 21A, the first thin portion 21B, and the second thin portion 21C as viewed in the thickness direction z. With this configuration, it is possible to reduce the stress acting on and near the periphery of the semiconductor element 1 while enlarging the size of the semiconductor element 1 mounted on the island portion 21.

The semiconductor device according to the present disclosure is not limited to the above-described embodiments. The specific configurations of the respective parts of the semiconductor device according to the present disclosure may be freely designed.

The present disclosure includes the embodiments described in the following clauses.

### Clause 1.

A semiconductor device comprising:
a first conductive member having an island portion;
a semiconductor element disposed on one side of a thickness direction of the island portion;
a sealing resin covering the semiconductor element and at least a part of the first conductive member,
wherein the island portion is located on one side of a first direction perpendicular to the thickness direction and comprises a first edge portion extending in a second direction perpendicular to the thickness direction and the first direction,
the first edge portion has a first step portion covered by the sealing resin and formed on one side of the second direction with respect to the semiconductor element in the second direction, and
the first step portion is recessed toward another side in the first direction, on the one side of the second direction rather than on another side of the second direction.

### Clause 2.

The semiconductor device according to clause 1,
wherein the island portion has a first main surface facing the one side in the thickness direction, and a second main surface facing another side in the thickness direction, and
the semiconductor element has an element first surface facing the one side in the thickness direction, and an element second surface facing the other side in the thickness direction and is opposed to the first main surface.

### Clause 3.

The semiconductor device according to clause 2,
wherein the island portion comprises a main portion,
the main portion has at least a part of the first main surface and the second main surface.

### Clause 4.

The semiconductor device according to clause 3,
wherein the island portion comprises a first thin portion connected to the one side of the first direction of the main portion,
the first thin portion has a part of the first main surface, and a first intermediate surface facing the other side in the thickness direction and located between the first main surface and the second main surface in the thickness direction, and
the first thin portion comprises at least a part of the first edge portion.

### Clause 5.

The semiconductor device according to clause 4, wherein the first step portion is formed in the first thin portion.

### Clause 6.

The semiconductor device according to clause 3 or 4, wherein the first step portion is formed in the main portion.

### Clause 7.

The semiconductor device according to any one of clauses 4 to 6, wherein the semiconductor element overlaps the main portion and the first thin portion as viewed in the thickness direction.

### Clause 8.

The semiconductor device according to any one of clauses 1 to 7, wherein the first edge portion has a first recess comprising the first step portion and being recessed toward the other side in the first direction.

### Clause 9.

The semiconductor device according to any one of clauses 1 to 8,
wherein the island portion is located on the other side of the first direction and comprises a second edge portion extending in the second direction,
the second edge portion has a second step portion covered by the sealing resin and formed on the one side of the second direction with respect to the semiconductor element in the second direction, and
the second step portion is recessed toward the one side in the second direction, on the one side of the first direction rather than on the other side of the second direction.

### Clause 10.

The semiconductor device according to any one of clauses 4 to 7,
wherein the island portion comprises a second edge portion being located on the other side of the first direction and extending in the second direction,
the second edge portion has a second step portion covered by the sealing resin and formed on the one side of the second direction with respect to the semiconductor element in the second direction, and
the second step portion is recessed toward the one side in the first direction, on the one side of the second direction rather than on the other side of the second direction,
the island portion comprises a second thin portion connected to the other side of the first direction of the main portion,
the second thin portion has a part of the first main surface and a second intermediate surface facing the other side in the thickness direction and being located between the first main surface and the second main surface in the thickness direction, and
the second thin portion comprises at least a part of the second edge portion

### Clause 11.

The semiconductor device according to clause 10, wherein the second step portion is formed in the second thin portion.

### Clause 12.

The semiconductor device according to clause 10, wherein the second step portion is formed in the main portion.

### Clause 13.

The semiconductor device according to any one of clauses 10 to 12, wherein the semiconductor element overlaps the main portion and the second thin portion as viewed in the thickness direction.

### Clause 14.

The semiconductor device according to any one of clauses 9 to 13, wherein the second edge portion has a second recess configured to include the second step portion and recessed toward the one side in the first direction.

### Clause 15.

The semiconductor device according to any one of clauses 1 to 14,
wherein the semiconductor element has a first electrode disposed on the one side of the thickness direction and a second electrode disposed on the other side of the thickness direction, and
the second electrode is conductively bonded to the one side of the thickness direction of the island portion.

### Clause 16.

The semiconductor device according to clause 15, further comprising a second conductive member conductively bonded to the first electrode and a third conductive member conductively bonded to a third electrode,
wherein the semiconductor element has the third electrode disposed on one side of the thickness direction.

REFERENCE NUMERALS

| | |
|---|---|
| A1, A2, A3, A4, A5: Semiconductor | 1: Semiconductor element |
| device | |
| 101: Element first surface | 102: Element second surface |
| 11: First electrode; | 12: Second electrode |
| 13: Third electrode | 19: Conductive bonding material |
| 2: First conductive member | 201: First main surface |
| 202: Second main surface | 203: First intermediate surface |
| 204: Second intermediate surface | 21: Island portion |
| 21A: Main portion | 21B: First thin portion |
| 21C: Second thin portion | 211: First edge portion |
| 211a, 211c: First step portion | 211b: First recess |
| 212: Second edge portion | 212a, 212c: Second step portion |
| 212b: Second recess | 213: Third edge portion |
| 214: Recessed groove | 22: First terminal portion |
| 23: Through hole | 3: Second conductive member |
| 31: Pad portion | 32: Second terminal portion |
| 39: Conductive bonding material | 4: Third conductive member |
| 41: Pad portion | 42: Third terminal portion |
| 49: Conductive bonding material | 5: Sealing resin |
| 51: First resin surface | 52: Second resin surface |
| 53: Third resin surface | 54: Fourth resin surface |
| 55: Fifth resin surface | 56: Sixth resin surface |

1. A semiconductor device comprising:
a first conductive member having an island portion;
a semiconductor element disposed on one side of a thickness direction of the island portion;
a sealing resin covering the semiconductor element and at least a part of the first conductive member,
wherein the island portion is located on one side of a first direction perpendicular to the thickness direction and comprises a first edge portion extending in a second direction perpendicular to the thickness direction and the first direction,
the first edge portion has a first step portion covered by the sealing resin and formed on one side of the second direction with respect to the semiconductor element in the second direction, and
the first step portion is recessed toward another side in the first direction, on the one side of the second direction rather than on another side of the second direction.

2. The semiconductor device according to claim 1,
wherein the island portion has a first main surface facing the one side in the thickness direction, and a second main surface facing another side in the thickness direction, and
the semiconductor element has an element first surface facing the one side in the thickness direction, and an element second surface facing the other side in the thickness direction and is opposed to the first main surface.

3. The semiconductor device according to claim 2,
wherein the island portion comprises a main portion,
the main portion has at least a part of the first main surface and the second main surface.

4. The semiconductor device according to claim 3,
wherein the island portion comprises a first thin portion connected to the one side of the first direction of the main portion,
the first thin portion has a part of the first main surface, and a first intermediate surface facing the other side in the thickness direction and located between the first main surface and the second main surface in the thickness direction, and
the first thin portion comprises at least a part of the first edge portion.

5. The semiconductor device according to claim 4, wherein the first step portion is formed in the first thin portion.

6. The semiconductor device according to claim 3, wherein the first step portion is formed in the main portion.

7. The semiconductor device according to claim 4, wherein the semiconductor element overlaps the main portion and the first thin portion as viewed in the thickness direction.

8. The semiconductor device according to claim 1, wherein the first edge portion has a first recess comprising the first step portion and being recessed toward the other side in the first direction.

9. The semiconductor device according to claim 1,
wherein the island portion is located on the other side of the first direction and comprises a second edge portion extending in the second direction,
the second edge portion has a second step portion covered by the sealing resin and formed on the one side of the second direction with respect to the semiconductor element in the second direction, and
the second step portion is recessed toward the one side in the second direction, on the one side of the first direction rather than on the other side of the second direction.

10. The semiconductor device according to claim 4,
wherein the island portion comprises a second edge portion being located on the other side of the first direction and extending in the second direction,
the second edge portion has a second step portion covered by the sealing resin and formed on the one side of the second direction with respect to the semiconductor element in the second direction, and
the second step portion is recessed toward the one side in the first direction, on the one side of the second direction rather than on the other side of the second direction,
the island portion comprises a second thin portion connected to the other side of the first direction of the main portion,
the second thin portion has a part of the first main surface and a second intermediate surface facing the other side in the thickness direction and being located between the first main surface and the second main surface in the thickness direction, and
the second thin portion comprises at least a part of the second edge portion

11. The semiconductor device according to claim 10, wherein the second step portion is formed in the second thin portion.

12. The semiconductor device according to claim 10, wherein the second step portion is formed in the main portion.

13. The semiconductor device according to claim 10, wherein the semiconductor element overlaps the main portion and the second thin portion as viewed in the thickness direction.

14. The semiconductor device according to claim 9, wherein the second edge portion has a second recess configured to include the second step portion and recessed toward the one side in the first direction.

15. The semiconductor device according to claim 1,
wherein the semiconductor element has a first electrode disposed on the one side of the thickness direction and a second electrode disposed on the other side of the thickness direction, and
the second electrode is conductively bonded to the one side of the thickness direction of the island portion.

16. The semiconductor device according to claim 15, further comprising a second conductive member conductively bonded to the first electrode and a third conductive member conductively bonded to a third electrode,
wherein the semiconductor element has the third electrode disposed on one side of the thickness direction.
